(19) United States
(12) Patent Application Publication
(10) Pub. No.: US 2024/0332891 A1
(43) Pub. Date: Oct. 3, 2024

(54) OPTICAL DEVICE AND METHOD OF MANUFACTURING OPTICAL DEVICE

(71) Applicant: FURUKAWA ELECTRIC CO., LTD., Tokyo (JP)

(72) Inventors: Ayato OKADA, Tokyo (JP); Atsushi OGURI, Tokyo (JP); Masaya NAKAZUMI, Tokyo (JP); Naoki HAYAMIZU, Tokyo (JP)

(73) Assignee: FURUKAWA ELECTRIC CO., LTD., Tokyo (JP)

(21) Appl. No.: 18/738,132

(22) Filed: Jun. 10, 2024

Related U.S. Application Data
(63) Continuation of application No. PCT/JP2022/046272, filed on Dec. 15, 2022.

(30) Foreign Application Priority Data
Dec. 15, 2021 (JP) 2021-202997

(51) Int. Cl. H01S 5/026; H01S 5/02251; H01S 5/02253

(52) U.S. Cl. CPC H01S 5/0267; H01S 5/02253; H01S 5/02251

(57) ABSTRACT

An optical device includes: a first optical component configured to transmit light between a first end and a second end; a second optical component configured to either focus and couple the light to the first end or collimate the light emitted from the first end; and a transmissive component interposed between the first optical component and the second optical component and configured to transmit the light emitted from the first end or incident on the first end, and make a distance between the second optical component and the first end longer than in a case without the transmissive component.

This application is a continuation of International Application No. PCT/JP2022/046272, filed on Dec. 15, 2022 which claims the benefit of priority of the prior Japanese Patent Application No. 2021-202997, filed on Dec. 15, 2021, the entire contents of which are incorporated herein by reference.

### BACKGROUND

The present disclosure relates to an optical device and a method of manufacturing the optical device.

Optical devices that transmit a laser beam between a lens and an optical fiber have been known (e.g., WO 2017/134911 A).

### SUMMARY

In the known optical devices, adjustment of the distance between two optical components is significantly important from the viewpoint of suppressing the decrease in optical transmission efficiency. It would be beneficial if the distance between these two optical components could be adjusted more easily or quickly.

There is a need for an optical device and a method of manufacturing the optical device equipped with a novel and improved configuration, which makes it possible, for example, to adjust the distance between two optical components more easily or quickly.

According to one aspect of the present disclosure, there is provided an optical device including: a first optical component configured to transmit light between a first end and a second end; a second optical component configured to either focus and couple the light to the first end or collimate the light emitted from the first end; and a transmissive component interposed between the first optical component and the second optical component and configured to transmit the light emitted from the first end or incident on the first end, and make a distance between the second optical component and the first end longer than in a case without the transmissive component.

According to another aspect of the present disclosure, there is provided a method of manufacturing an optical device including: a first optical component configured to transmit light between a first end and a second end; a second optical component configured to either focus and couple the light to the first end or collimate the light emitted from the first end; a transmissive component interposed between the first optical component and the second optical component and configured to transmit the light emitted from the first end or incident on the first end, and make a distance between the second optical component and the first end longer than in a case without the transmissive component; and a base configured to support the first optical component, the second optical component, and the transmissive component, the method including: a first process of fixing the first optical component to the base; a second process of provisionally arranging the second optical component, in a state where an adjustment component having a thickness greater in an optical axis direction than the transmissive component and transmitting light is arranged in place of the transmissive component, such that the collimated light inputted into the second optical component transmits through the second optical component and the adjustment component and is focused and coupled at the first end, or such that the light from the first end transmits through the adjustment component and is inputted into the second optical component to be collimated; a third process of determining the transmissive component having a thickness suitable to a case where the second optical component is fixed in a predetermined position with respect to the base, based on a position in the optical axis direction of the second optical component provisionally arranged in the second process; and a fourth process of fixing the transmissive component determined in the third process and the second optical component to the base.

### BRIEF DESCRIPTION OF THE DRAWINGS

FIG. 1 is an exemplary and schematic perspective view of an optical device according to a first embodiment;

FIG. 2 is an exemplary and schematic plan view of an optical fiber and an end cap included in the optical device of the first embodiment;

FIG. 3 is a diagram illustrated to describe an optical path in a transmissive component included in the optical device of the first embodiment;

FIG. 4 is an exemplary and schematic side view of a part of the optical device of the first embodiment;

FIG. 5 is an exemplary and schematic frontal view of a part of the optical device of the first embodiment;

FIG. 6 is an exemplary and schematic side view illustrating a second process of a method of assembling the optical device of the first embodiment;

FIG. 7 is an exemplary and schematic side view illustrating a fourth process of the method of assembling the optical device according to the first embodiment;

FIG. 8 is an exemplary and schematic side view illustrating a second process of a method of assembling an optical device according to a first modification of an embodiment;

FIG. 9 is an exemplary and schematic perspective view of an optical device according to a second modification of an embodiment;

FIG. 10 is an exemplary and schematic perspective view of an optical device according to a third modification of an embodiment;

FIG. 11 is an exemplary schematic configuration diagram of an optical device according to a second embodiment;

FIG. 12 is an exemplary and schematic plan view of an optical device according to a third embodiment;

FIG. 13 is an exemplary and schematic plan view of a light-emitting module included in the optical device of the third embodiment;

FIG. 14 is an exemplary and schematic perspective view of a base included in the optical device of the third embodiment;

FIG. 15 is an exemplary and schematic plan view of a part of an optical device according to a fourth modification of an embodiment;

FIG. 16 is an exemplary and schematic side view of a sub-unit included in the optical device according to the fourth modification of an embodiment; and

FIG. 17 is an exemplary and schematic plan view of a part of an optical device according to a fifth modification of an embodiment.

### DETAILED DESCRIPTION

Exemplary embodiments and modifications are now described. The configurations of embodiments and modifications herein, as well as the operations and results (effects) achieved by the configurations, are merely illustrative. The present disclosure is implementable by configurations other than those disclosed in the embodiments and modifications herein. Additionally, according to the present disclosure, it is possible to achieve at least one of various effects obtained by the configuration (including derivative effects).

The multiple embodiments and modifications described herein have similar configurations. Thus, according to the configurations of the respective embodiments and modifications, similar operations and effects based on the similar configurations are achievable. Additionally, these similar configurations are hereinafter assigned with similar reference numerals, and redundant descriptions are omitted in some cases.

Herein, ordinal numbers are assigned for convenience to distinguish components, parts, or the like and do not indicate priority or sequence.

Further, in each drawing, the X1 direction is represented by an arrow X1, the X2 direction is represented by an arrow X2, the Y direction is represented by an arrow Y, and the Z direction is represented by an arrow Z. The X1 direction, Y direction, and Z direction intersect each other and are mutually orthogonal. Additionally, the X1 direction and the X2 direction are opposite to each other.

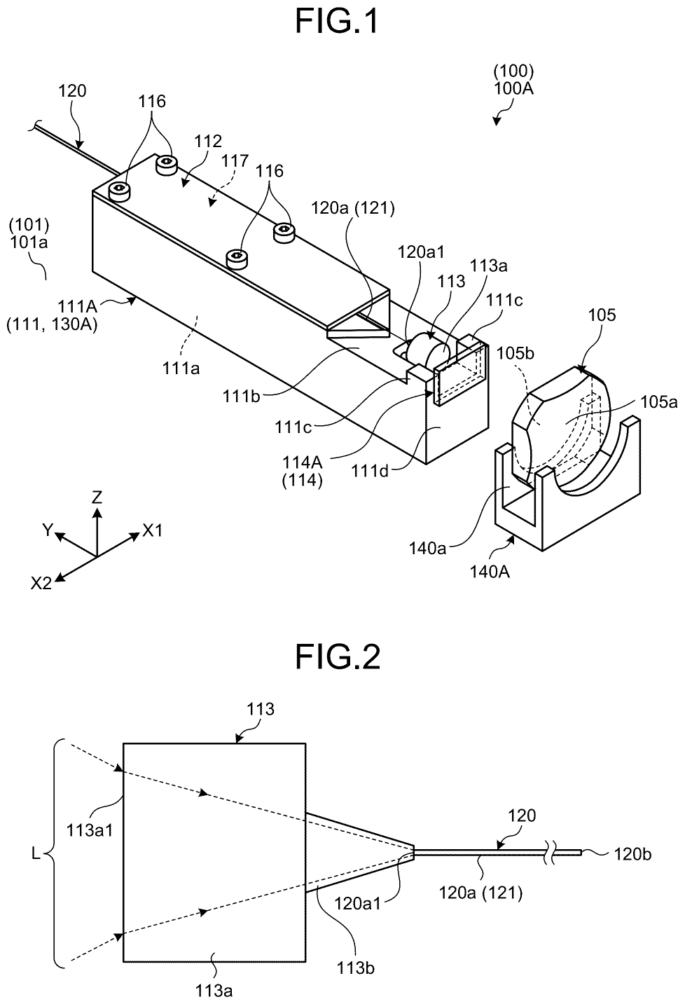

FIG. 1 is a perspective view of an optical device 100A (100). As illustrated in FIG. 1, the optical device 100 includes an optical fiber 120, a lens 105, an end cap 113, and a transmissive component 114A (114). The optical fiber 120, the end cap 113, and the transmissive component 114A are supported by a support member 111A (111), and the lens 105 is supported by a lens holder 140A. Additionally, the support member 111A and the lens holder 140A are each mounted on a surface 101a of a base 101.

In the optical device 100A, for example, collimated light that is input to an end facet 105a of the lens 105 is focused by the lens 105, and is coupled to a tip 120al of the optical fiber 120 through an end facet 105b of the lens 105, the transmissive component 114A, and the end cap 113 in this order. In this case, the lens 105 functions, for example, as a focusing lens that focuses laser beams being collimated in at least one of the fast axis and the slow axis.

Further, in the optical device 100A, for example, light emitted from the tip 120al of the optical fiber 120 may pass through the end cap 113, the transmissive component 114A, and the lens 105 in this order, and be emitted from the end facet 105a of the lens 105. In this case, the lens 105 functions, for example, as a collimating lens that collimates laser beams in at least one of the fast axis and the slow axis.

The optical fiber 120 is an example of a first optical component, and the tip 120al is an example of one end. Additionally, the lens 105 is an example of a second optical component that focuses and combines collimated light onto the tip 120al or collimates light emitted from the tip 120al. In the present embodiment, the numerical aperture of the optical fiber 120 is, for example, 0.2 or more, and the power of the light being transmitted is, for example, 100 [W] or more.

The support member 111A has a rectangular parallelepiped shape extending in the Y direction and supports the optical fiber 120 that extends in the Y direction. Additionally, the support member 111A has a face 111a facing the opposite direction of the Z direction and a face 111b facing the Z direction. The face 111a is joined to the surface 101a of the base 101 by, for example, soldering, brazing, or the like.

A cover 112 intersects and is orthogonal to the Z direction. The cover 112 has a rectangular and plate-like shape that is short in the X1 and X2 directions, long in the Y direction, and thin in the Z direction. The cover 112 is fixed to the support member 111A with, for example, a fixing member 116 such as a screw. The optical fiber 120 is supported by the support member 111A and the cover 112. The support member 111A and the cover 112 are both made of a material with high thermal conductivity. The optical fiber 120 is partially housed within a housing chamber 117, which is provided between the support member 111A and the cover 112 and extends in the X direction. Within the housing chamber 117, an optical processing mechanism may be provided to process leakage light from the optical fiber 120.

The end cap 113 and the transmissive component 114A are each attached to the support member 111A by, for example, an adhesive. The end cap 113 and the transmissive component 114A will be described in detail later.

The lens 105 is attached to the base 101 by the lens holder 140A. The lens holder 140A is joined onto the surface 101a of the base 101 by, for example, soldering, brazing, adhesion, or the like.

The lens 105 is attached to the lens holder 140A through an adhesive (not illustrated). The lens holder 140A has an end facet 140a, which intersects and is orthogonal to the Z direction. The end facet 140a, the end facet 105b of the lens 105 opposite to the end facet 105a on the convex side are adjacent in the Y direction, which is the optical axis direction of the light transmitted between the optical fiber 120 and the lens 105, and they are joined to each other through an adhesive that intervenes between the end facet 140a and the end facet 105a. In other words, the end facet 140a supports the lens 105 through the adhesive. The end facet 140a is an example of a first supporting surface, and the adhesive is an example of a first adhesive.

The adhesive is, for example, a photo-curable adhesive, a thermosetting adhesive, or a moisture-curing adhesive.

If the adhesive deteriorates and causes the lens 105 to shift in the direction intersecting the optical axis, misalignment of the optical axis occurs, resulting in a decrease in the transmission efficiency of light by the optical device 100A. Additionally, if the deterioration of the adhesive causes the lens 105 to tilt with respect to the optical axis, this causes the optical axis to tilt, resulting in a decrease in the transmission efficiency of light by the optical device 100A, in this case as well. On the other hand, in the case where the lens 105 shifts in the optical axis direction due to the deterioration of the adhesive, the degree of reduction in transmission efficiency relative to the amount of displacement is lower compared to the case where the lens 105 shifts in a direction intersecting the optical axis or tilts with respect to the optical axis. In this regard, as described above, in the configuration where the adhesive joins the adjacent end facets 140a and 105a in the optical axis direction, even if the adhesive deteriorates, there may be instances where the lens 105 shifts in the optical axis direction, but the lens 105 is less prone to misalignment in the direction intersecting the optical axis or tilting with respect to the optical axis, and so it may be said that this configuration is a highly robust configuration that is less susceptible to a decrease in the transmission efficiency due to adhesive deterioration. However, even in the configuration where the end facets 140a and 105a, which are adjacent to each other in the optical axis direction, are joined with the adhesive, if the thickness of the adhesive is too great, there is a risk that the lens 105 will be tilted. From this point of view, the thickness of the adhesive is preferably 100 [μm] or less.

The end cap 113 is provided in contact with the tip 120al of a stripped end portion 120a (core wire 121) of the optical fiber 120, with a gap between the end cap 113 and the transmissive component 114A. In one example, the end cap 113 is integrated with the tip 120al, for example, by fusion bonding or the like.

FIG. 2 is a plan view illustrating the tip of the optical fiber 120 and the end cap 113. In FIG. 2, the optical path of a laser beam L to the tip 120al of the core wire 121 of the optical fiber 120 within the end cap 113 is illustrated by a broken line. In a configuration in which the end cap 113 is not provided, if a laser beam condensed by the lens 105 or the like arrives toward the tip 120al of the stripped end portion 120a, the power density excessively increases due to the reduction in beam diameter at the tip 120al serving an interface, resulting in excessive temperature rise and potential damage to the tip 120a1. In this regard, the present embodiment allows the laser beam L to reach an end facet 113al of the end cap 113, which has a larger area than the tip 120al, i.e., a larger area than the cross-sectional area of the optical fiber 120, with a larger beam diameter and lower power density, thereby enabling suppression of excessive temperature rise and consequent damage at both the end facet 113a1 serving as the interface and the tip 120al of the core wire 121. The end cap 113 is an example of a mitigating member. Moreover, an antireflection (AR) coating is applied to the end facet 113al of the end cap 113 on the opposite side from a protrusion 113b, forming an antireflection film. This causes the reflection of light at the end facet 113a1 to be suppressed.

The laser beam coupled to the tip 120al of the optical fiber 120 is transmitted to an end portion 120b of the optical fiber 120 on the opposite side from the tip 120al. The end portion 120b is an example of the other end. Additionally, it may be said that the optical fiber 120 and the end cap 113 constitute a single first optical component. In this case, the end facet 113a1 of the end cap 113 is an example of one end.

As illustrated in FIG. 1, the transmissive component 114A is interposed between the optical fiber 120 and the lens 105 and the end cap 113 and the lens 105, respectively, with a gap therebetween, and allows the transmission of light from both the tip 120al and the end facet 113a1 and the transmission of light both to the end facet 113a1 and the tip 120a1.

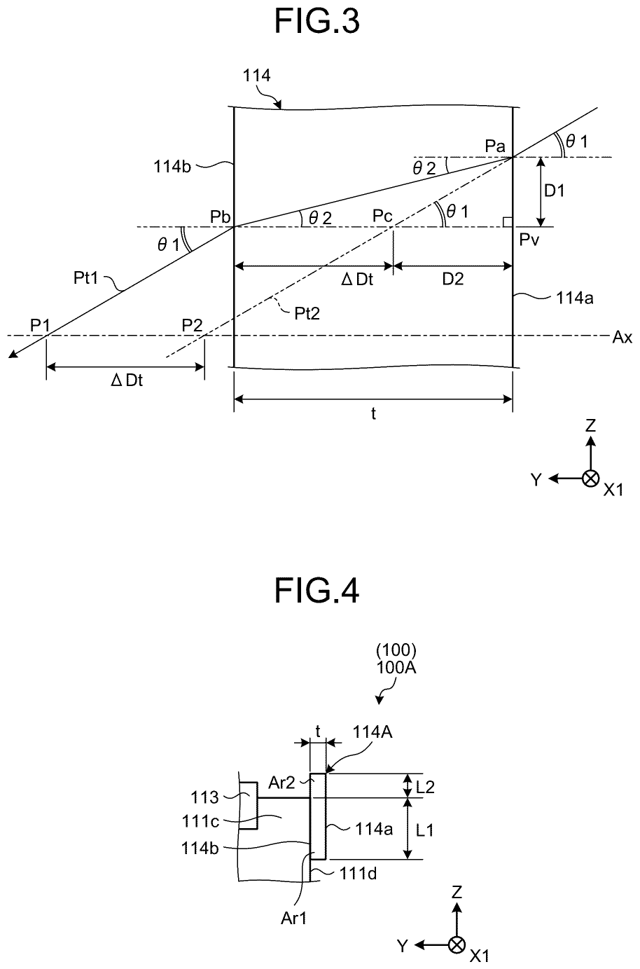

FIG. 3 is a partial side view of the transmissive component 114A and a diagram illustrated to describe the optical path within the transmissive component 114A. In FIG. 3, in the transmissive component 114A, there is a case where the laser beam reaches a point Pa on an end facet 114a of the transmissive component 114A at an incident angle θ1, is refracted at the point Pa at a refraction angle θ2 to enter inside the transmissive component 114A, travels through the transmissive component 114A to reach a point Pb on an end facet 114b at an incidence angle θ2, is refracted at the point Pb at a refraction angle θ1, and then exits the transmissive component 114A. In this case, the refractive index n (>1) of the transmissive component 114A, being higher than the refractive index of air (=1), implies that θ1>θ2. Furthermore, in this case, the intersection between an optical path Pt1 (illustrated by a solid line from the point Pa through the point Pb to a point P1) with the transmissive component 114A interposed and a point with an optical axis Ax is denoted as P1, the intersection between an optical path Pt2 (illustrated by a dashed line from the point Pa through a point Pc to a point P2) without the transmissive component 114A and a point with the optical axis Ax is denoted as P2, and the distance between the points P1 and P2 is denoted as ΔDt. In the case where the lens 105 is arranged so that the optical path Pt1 and the optical path Pt2 are focused at the tip 120al of the optical fiber 120, the distance between the lens 105 and the tip 120al in the case where the transmissive component 114A is present is longer by the distance ΔDt compared to the distance between the lens 105 and the tip 120al in the case where the transmissive component 114A is absent. In other words, it may be seen from FIG. 3 that the transmissive component 114A allows the distance between the lens 105 and the tip 120al of the optical fiber 120 to be longer than the case where the transmissive component 114A is absent.

In this context, as illustrated in FIG. 3, let the thickness of the transmissive component 114A be denoted as t, let the intersection between the perpendicular line from the point Pb toward the end facet 114a and the end facet 114a be denoted as Pv, let the intersection between a line segment connecting the point Pb to the point Pv and the optical path Pt2 be denoted as Pc, let the distance between the points Pa and Pv be denoted as D1, let the distance between the points Pc and Pv be denoted as D2, and given that tanθ1≈θ1 (since θ1≈θ) and tanθ2≈θ2 (since θ2≈θ), the following Equations (1) to (3) hold:

$$D 1 = t \times tan θ 2 \approx t \times θ 2 \qquad ( 1 )$$

$$D 2 = D 1 / tan θ 1 \approx t \times θ 2 / θ 1 \qquad ( 2 )$$

$$t = Δ Dt + D 2 \approx Δ Dt + t \times θ 2 / θ 1 \qquad ( 3 )$$

By rearranging Equation (3),

the following equation is derived:

$$Δ Dt \approx t \times ( 1 - θ 2 / θ 1 ) \qquad ( 4 )$$

Given that the refractive index of the transmissive component 114A is n, according to Snell's Law, the following Equation is obtained:

$$θ 2 / θ 1 = 1 / n \qquad ( 5 )$$

Thus, from Equations (4) and (5), the following Equation (6) is obtained:

$$Δ Dt \approx t \times ( 1 - 1 / n ) \qquad ( 6 )$$

In this way, the difference in the distance between the lens 105 and the tip 120al of the optical fiber 120 depending on the presence or absence of the transmissive component 114A may be calculated on the basis of the thickness t of the transmissive component 114A and the refractive index n of the transmissive component 114A.

Further, the transmissive component 114A is made of, for example, synthetic quartz that has a low absorption rate for the laser beam. This allows for the suppression of temperature increase in the transmissive component 114A due to the absorption of the laser beam. In this case, the refractive index n of synthetic quartz is approximately 1.5, so the following Equation (6) becomes:

$$Δ Dt \approx t / 3 \qquad ( 7 )$$

In other words, the insertion of the transmissive component 114A with the thickness t results in an increase in the distance between the lens 105 and the tip 120al by approximately one-third of the thickness t.

The configuration including the transmissive component 114A as described above enables the distance in the optical axis direction between the lens 105 and the tip 120al to be longer by ΔDt than the length of the distance in the case where the transmissive component 114A is absent as described above, and additionally, positioning the transmissive component 114A with a thickness of 3×ΔDt between the lens 105 and the tip 120al, the focal point of the laser beam from the lens 105 to the tip 120al enables the focal point of the laser beam from the lens 105 to the tip 120al to be precisely positioned at the tip 120al. With this configuration, for example, even if there are individual differences in component dimensions, manufacturing variations, or the like causing the distance between the lens 105 and the tip 120al to deviate from the design value, calibration may be made by adjusting the thickness t of the transmissive component 114A in the Y direction, that is, by selecting the transmissive component 114A with an appropriate thickness t from among a plurality of the transmissive components 114A with different thicknesses t, without moving the positions of the lens 105 and the optical fiber 120. Fine adjustments to the positions of the optical fiber 120 and the lens 105 are difficult in some cases. Thus, the advantage is gained that by selecting the transmissive component 114A based on the measurement result of the product, the manufacturing of the optical device 100A may be made more easier or faster. Moreover, as long as the transmissive component 114A may transmit light between the lens 105 and the tip 120al (or the end cap 113), it provides the same effects regardless of its position in the Y direction. Thus, the transmissive component 114A does not require strict positioning in the Y direction, so it may also be advantageously mounted relatively easily. Furthermore, depending on the material of the adhesive used to support the lens 105, there is a risk that the adhesive may deteriorate when exposed to laser beam (particularly short wavelength laser beam with a wavelength of 500 [nm] or less), causing the position of the lens 105 to shift in the optical axis direction during use of the optical device 100A, thereby potentially reducing the efficiency of light transmission. Even in such a case, the present embodiment makes it possible for the light transmission efficiency to be restored by a relatively simple operation such as replacing the transmissive component 114A in response to the deviation in the optical axis direction.

FIG. 4 is a partial side view of the optical device 100A including the transmissive component 114A. As illustrated in FIG. 4, the transmissive component 114A has end facets 114a and 114b. The end facet 114a, which is in the opposite direction to the Y direction, serves as an interface facing the lens 105, intersects with the Y direction, and is orthogonal to the Y direction.

Additionally, the end facet 114b in the Y direction serves as an interface facing the tip 120al of the optical fiber 120 or the end cap 113, intersects with the Y direction, and is orthogonal to the Y direction. In other words, the end facets 114a and 114b are planes parallel to each other, and the transmissive component 114A has a flat plate shape. Such a shape of the transmissive component 114A makes it possible to suppress an increase in labor and costs required for manufacturing the transmissive component 114A. The end facet 114a is an example of a second plane, and the end facet 114b is an example of a first plane.

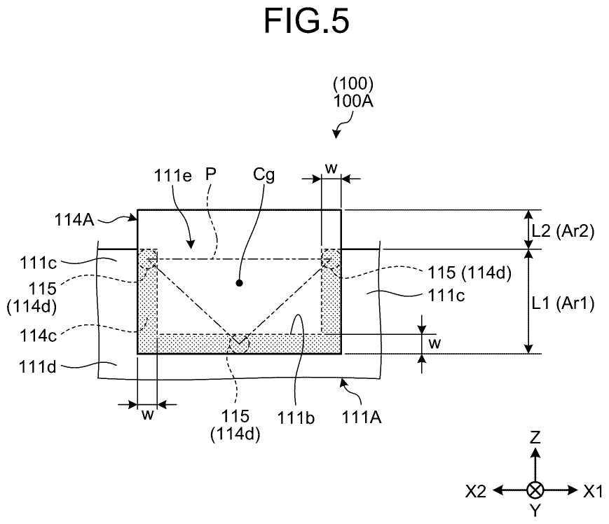

Further, an end facet 111d of the support member 111A in the opposite direction to the Y direction intersects with the Y direction and is orthogonal to the Y direction. The end facet 114b of the transmissive component 114A faces the end facet 111d and is attached to the end facet 111d through an adhesive 115 (not illustrated in FIG. 4, refer to FIG. 5). In other words, the support member 111A supports the transmissive component 114 as well as the optical fiber 120 or the end cap 113. With this configuration, the number of parts may be reduced compared to the case where they are each supported by separate support members, resulting in a decrease in manufacturing labor and costs. Moreover, the support member 111A may further support the lens 105. The end facet 111d is an example of a third supporting surface that supports the transmissive component 114A, and the adhesive 115 is an example of the second adhesive.

FIG. 5 is a frontal view of a part of the optical device 100A including the transmissive component 114A. As illustrated in FIG. 1, two protrusions 111c that protrude from the face 111b in the Z direction are provided at the opposite ends of the support member 111A in the Y direction. Then, as illustrated in FIGS. 1 and 5, in the support member 111A, a recess 111e that is open in a U-shape in the Z direction is formed by these two protrusions 111c and the face 111b. The transmissive component 114A is attached to the end facet 111d in such a way as to cover the recess 111e in the Y direction.

As illustrated in FIG. 5, the peripheral edge of the transmissive component 114A, that is, the end of the transmissive component 114A in the direction intersecting the Y direction, partially overlaps the peripheral edge of the recess 111e of the support member 111A in the Y direction. The adhesive 115 joins the end facet 111d of the support member 111A and an opposing region 114c (a region with a dot pattern) that overlaps the peripheral edge of the recess 111e in the Y direction of the end facet 114b (see FIG. 4) of the transmissive component 114A. The opposing region 114c is a linear and band-shaped region having a width w and extending along the peripheral edge of the transmissive component 114A and the recess 111e. The adhesive 115 is dispersed and arranged at two or more locations in the opposing region 114c, with three locations being illustrated as an example in the present embodiment. In other words, the support member 111A supports multiple locations spaced apart from each other in the opposing region 114c through the adhesive 115. The location within the opposing region 114c where the adhesive 115 is applied is an example of a supported portion 114d. From the viewpoint of stabilizing the posture of the transmissive component 114A, it is preferable to have the supported portion 114d at two or more locations, and more preferably at three or more locations. Additionally, as illustrated in FIG. 5, the supported portion 114d (the adhesive 115) when viewed in the Y-direction, is preferably positioned at three or more locations that coincide with the vertices of a hypothetical polygon P (a hypothetical triangle in the present embodiment) that includes the center of gravity Cf of the transmissive component 114A. Furthermore, from the viewpoint of reducing the weight of the transmissive component 114A and further preventing it from cracking, it is preferable for the width w of the opposing region 114c to be equal to or less than the thickness t of the transmissive component 114A in the Y direction (refer to FIG. 4).

Further, as illustrated in FIGS. 4 and 5, the transmissive component 114A includes a first region Ar1 whose ends in the X1 direction and the X2 direction are supported by the end facet 111d, and a second region Ar2 extending from the first region Ar1 in the Y direction. From the viewpoint of reducing the weight of the support member 111A and stabilizing the posture of the transmissive component 114A, it is preferable for the length L1 of the first region Ar1 in the Z direction to be greater than or equal to the length L2 of the second region Ar2 in the Z direction, it is more preferable for the length L1 to be at least 1.5 times greater than the length L2, and even more preferable for it to be two times or more. The X1 direction and the X2 direction are examples of a first direction, and the Z direction is an example of a second direction.

Moreover, at least one of the end facets 114a and 114b of the transmissive component 114A is applied with an AR coating, forming an antireflection film thereon. This suppresses the reflection of light on the end facets 114a and 114b where the AR coating is applied.

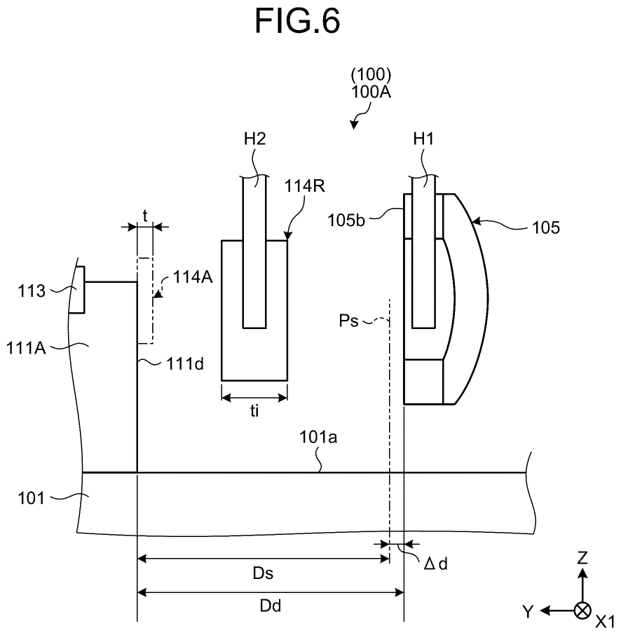

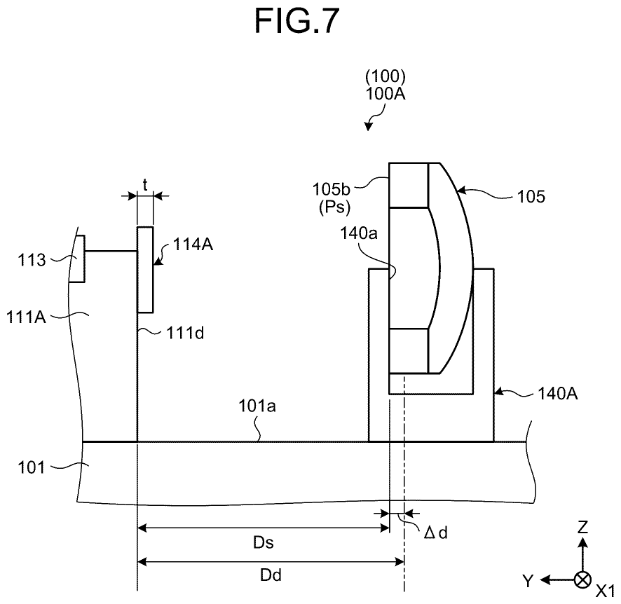

FIGS. 6 and 7 are side views of the optical device 100A illustrating the procedure for attaching the lens 105 and the transmissive component 114A, FIG. 6 illustrates an example of a second process of a method of assembling the optical device 100A, and FIG. 7 illustrates an example of a fourth process of the assembly method.

In the present embodiment, prior to attaching the lens 105 and the transmissive component 114A to the support member 111A, the optical fiber 120 and the end cap 113 are attached and fixed to the support member 111A (a first process).

Next, as illustrated in FIG. 6, without providing the transmissive component 114A between the tip 120al (the end cap 113) of the optical fiber 120 and the lens 105, and while maintaining a gap between each, an adjustment component 114R that transmits light is positioned. In this state, the position of the lens 105 in the Y direction is determined and provisionally placed such that the collimated light incident on the lens 105 transmits through the lens 105, the adjustment component 114R, and the end cap 113 to be focused and coupled to the tip 120al (the second process). Specifically, for example, it is possible to measure the light intensity received by the optical fiber 120 while changing the position of the lens 105 in the Y direction and to provisionally fix the lens 105 at the position where the received light intensity reaches the maximum. Moreover, the adjustment component 114R has a thickness ti that is thicker than the thickness t of the transmissive component 114A.

Next, in the second process, based on the relative positional relationship between the position of the lens 105 provisionally arranged in the Y direction and a predetermined fixed position Ps of the lens 105, the thickness t of the transmissive component 114A is determined (a third process). In the example of FIG. 6, in the third process, a distance Dd from the end facet 111d of the support member 111A to the end facet 105b of the lens 105 is measured, and a distance Δd between the distance Dd and a distance Ds from the end facet 111d to the end facet 140a (the fixed position Ps) of the lens holder 140A is calculated. In the case where the lens 105 is fixed between the end facet 140a of the lens holder 140A and the end facet 105b of the lens 105 through the adhesive (the first adhesive, not illustrated) having a thickness of s [μm], by replacing the transmissive component 114A with the adjustment component 114R, as derived from the aforementioned Equation (7), such that ti−t≈3×(Δd−s), the laser beam is made to be focused at the tip 120a1 and be coupled to the tip 120al. In other words, in this case, in the third process, the thickness t of the transmissive component 114A is determined by the following Equation (8):

$$t = ti - 3 \times Δ d + 3 s \qquad ( 8 )$$

In the case where a plurality of the transmissive components 114A having different thicknesses are prepared, the transmissive component 114A with the thickness closest to the value of t calculated by Equation (8) is selected as the transmissive component 114A to be mounted.

Next, as illustrated in FIG. 7, the transmissive component 114A selected in the third process mentioned above is fixed to the end facet 111d of the support member 111A through the adhesive 115 (refer to FIG. 5). This causes the transmissive component 114A to be fixed to the base 101 through the support member 111A. Subsequently, similar to the second process, the position of the lens 105 in the Y direction is re-determined, and the lens 105 is fixed to the base 101 through the lens holder 140A so that the collimated light input to the lens 105 focuses at the tip 120al and is coupled to the tip 120al (a fourth process).

On the other hand, instead of adjusting the thickness of the transmissive component 114A to the specific value s [μm], in some cases, it may be sufficient to adjust the thickness of the transmissive component 114A to, for example, s [μm] or less. In this case, in the third process, the transmissive component 114A with the thickness t satisfying the following Equation may be selected, and the aforementioned fourth process may be performed:

$$ti - 3 Δ d < t < ti - 3 Δ d + 3 s \qquad ( 9 )$$

In this case, it suffices to prepare a plurality of the transmissive components 114A with thicknesses differing by an interval of 3 s [μm], which reduces the number of components prepared for adjustment and consequently minimizes the efforts and costs required for manufacturing. Moreover, it is desirable for the thickness of the adhesive to be 100 [μm] or less.

Further, in the described configuration, the support member 111A is preferably made of a material with a thermal expansion coefficient having a value between the thermal expansion coefficients of the transmissive component 114A and the base 101. In the case where the transmissive component 114A is directly attached to the base 101, the difference between the thermal expansion coefficient of the base 101, which is made of, for example, copper-based metal, and that of the transmissive component 114A, which is made of, for example, synthetic quartz, will result in a significant disparity in volume change due to temperature fluctuations between the transmissive component 114A and the base 101. If this disparity in volume change exceeds the range that may maintain the joining state of the adhesive that fixes the transmissive component 114A to the base 101, there is a possibility that the transmissive component 114A may misalign, tilt, detach, or even crack with respect to the base 101, thereby compromising the desired optical characteristics in the optical device 100A. In this regard, in the present embodiment, the transmissive component 114A is fixed to the support member 111A with the thermal expansion coefficient adjusted, so the difference in volume changes due to temperature fluctuations between the transmissive component 114A and the support member 111A may be minimized compared to the case where the transmissive component 114A is directly fixed to the base 101. Thus, it becomes easier to maintain the fixed state of the transmissive component 114A by the support member 111A in the desired condition, consequently suppressing the loss of desired optical characteristics in the optical device 100A due to relative position or posture changes between the transmissive component 114A and the support member 111A. The support member 111A is an example of an intermediate member 130A.

As a material for the support member 111A (the intermediate members 130A) as described above, for example, copper-tungsten alloys (e.g., those containing approximately 10 to 20% by mass of Cu) or materials such as aluminum oxide are preferable. Additionally, to suppress heat generation caused by stray light (leakage light) within the optical device 100A, the support member 111A may be made of a material with a lower absorption rate of a laser beam having a wavelength of 400 [nm] or more and a wavelength of 520 [nm] or less than that of the material constituting the base 101 (copper in the present embodiment).

As described above, in the present embodiment, the transmissive component 114A is interposed between the tip 120al (one end) of the optical fiber 120 (first optical component) and the lens 105 (second optical component), with a gap between both the tip 120al and the lens 105, allowing for the transmission of a laser beam from the tip 120al to the lens 105 or light from the lens 105 to the tip 120al. The transmissive component 114A makes the distance between the tip 120al and the lens 105 longer than the case where the transmissive component 114A is absent. With such a configuration, by adjusting the thickness t of the transmissive component 114A, in other words, by selecting an appropriate transmissive component 114A from among multiple transmissive components 114A with different thicknesses t, the distance between the tip 120al and the lens 105 may be adjusted, thereby allowing the adjustment of the distance to be more easily, more quickly, or more precisely performed. Additionally, the thickness of the adhesive interposed between the lens 105 and the lens holder 140A in the Y direction may be easily or more reliably set to 100 [μm] or less, suppressing the tilting of the lens 105 due to the deterioration of the adhesive. Moreover, the thickness t of the transmissive component 114A may be adjusted with higher precision by polishing or the like.

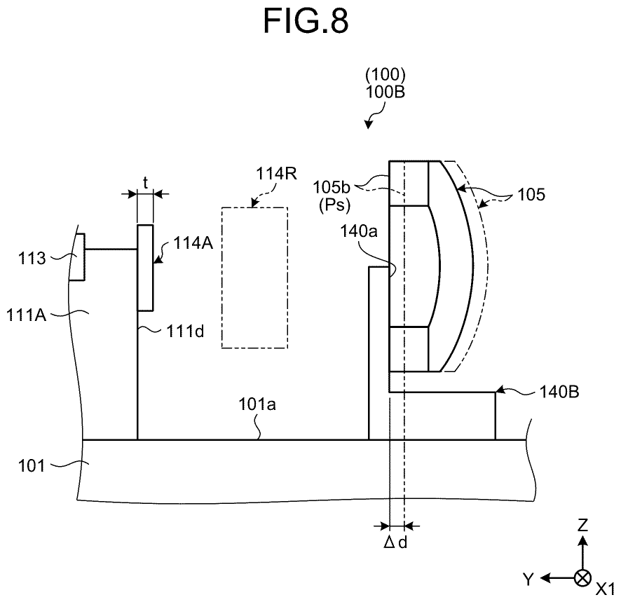

FIG. 8 is a side view illustrating the procedure for attaching the lens 105 and the transmissive component 114A of a first modification of the first embodiment, illustrating a second process of a method of assembling an optical device 100B (100). In the first modification, prior to the second process, a lens holder 140B is pre-fixed onto the base 101, and in the fourth process, the lens 105 is fixed onto the lens holder 140B. In this case, in the third process, the distance from the end facet 140a of the lens holder 140B to the end facet 105b of the lens 105 being provisionally fixed becomes a difference Ad. Subsequently, similarly to the first embodiment described above, the range of the thickness t of the transmissive component 114A that satisfies Equation (9) is determined, and if the plurality of transmissive components 114A having different thicknesses is prepared, the transmissive component 114A with the thickness t satisfying Equation (9) is selected as the transmissive component 114A to be mounted. In this way, it becomes possible to further reduce the labor and time required for the assembly of the optical device 100B while achieving more precise positioning of the optical fiber 120 and the lens 105.

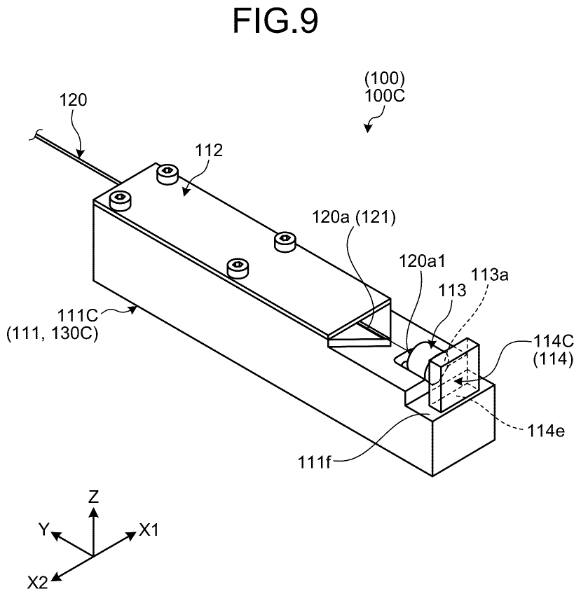

FIG. 9 is a perspective view of an optical device 100C (100) of a second modification of the first embodiment. As illustrated in FIG. 9, in the present modification, a side facet 114e of a transmissive component 114C (114) is placed on a face 111f of a support member 111C (111) facing the Z direction through an adhesive (not illustrated). The side facet 114e faces the opposite direction to the Z direction and faces the face 111f in the Z direction. With such a configuration, it is also possible for the support member 111C to support the transmissive component 114C. The face 111f is an example of a second supporting surface, and the side facet 114e is an example of a supported portion.

Further, in the present modification, the support member 111C is made of a material with a value between the thermal expansion coefficients of the transmissive component 114A and the base 101. In other words, in the present modification as well, the support member 111C is an example of an intermediate member 130C.

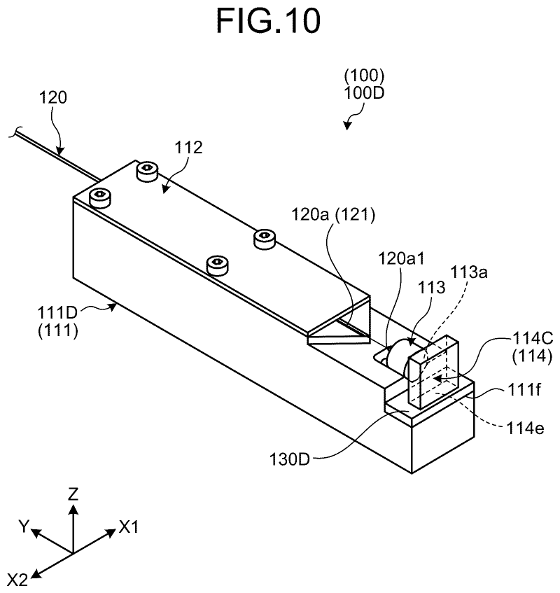

FIG. 10 is a perspective view of an optical device 100D (100) of a third modification of the first embodiment. As illustrated in FIG. 10, the optical device 100D of the present modification has a similar configuration to the optical device 100C of the second modification, except that the side facet 114e of the transmissive component 114A is supported by a support member 111D (111) through an intermediate member 130D. Also in the present modification, by providing the intermediate member 130D, similar effects may be achieved to the optical devices 100A and 100C of the first embodiment and the second modification, which are provided with the support members 111A and 111C as the intermediate members 130A and 130C, respectively. Moreover, in the present modification, the support member 111D may be made of a similar material to the base 101, or may be configured integrally with the base 101 as a part of the base 101.

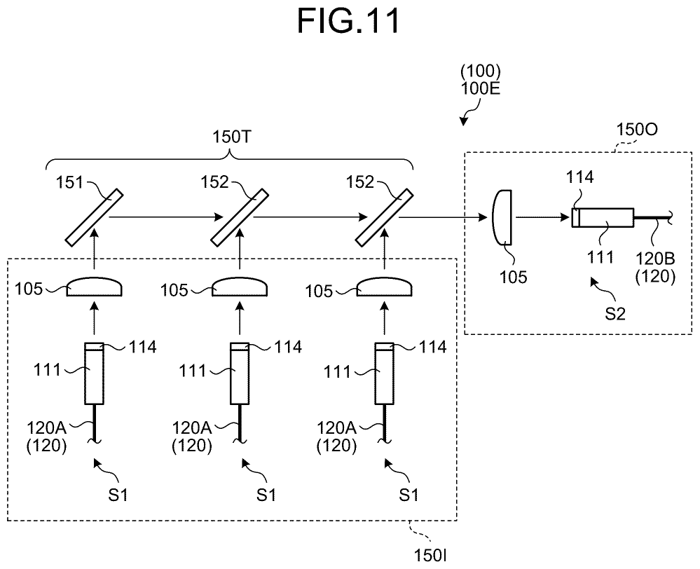

FIG. 11 is a schematic configuration diagram of an optical device 100E (100) of a second embodiment. The optical device 100E includes an input optical system 150I, a transmission optical system 150T, and an output optical system 1500. The input optical system 150I has a plurality of sets S1. The set S1 has a similar configuration to the optical devices 100A to 100D of the first embodiment and its modifications, that is, it includes an optical fiber 120A (120), the support member 111, the transmissive component 114, and the lens 105. Additionally, the output optical system 1500 has a set S2. The set S2 has a similar configuration to the optical devices 100A to 100D of the first embodiment and its modifications, that is, it includes an optical fiber 120B (120), the support member 111, the transmissive component 114, and the lens 105. However, in the set S1, the laser beam is transmitted from the optical fiber 120A to the lens 105, whereas in the set S2, the laser beam is transmitted from the lens 105 to the optical fiber 120B. Furthermore, the transmission optical system 150T includes a mirror 151 and a wavelength filter 152. The wavelength filter 152 allows the laser beam from one set S1 to pass through while reflecting the laser beam from another set S1. In the case where the wavelength filter 152 is a short-pass filter, it allows the laser beam with a shorter wavelength to pass through while reflecting the laser beam with a longer wavelength. Moreover, in the case where the wavelength filter 152 is a long-pass filter, it allows the laser beam with a longer wavelength to pass through while reflecting the laser beam with a shorter wavelength. Such a configuration makes it possible for the transmission optical system 150T to combine the laser beams from the plurality of sets S1 of the input optical system 150I and couple them to the set S2 of the output optical system 1500. The set S1 is an example of a first set, and the set S2 is an example of a second set. This optical device 100E may also achieve the effects by including the transmissive component 114, similar to the embodiments or modifications described above.

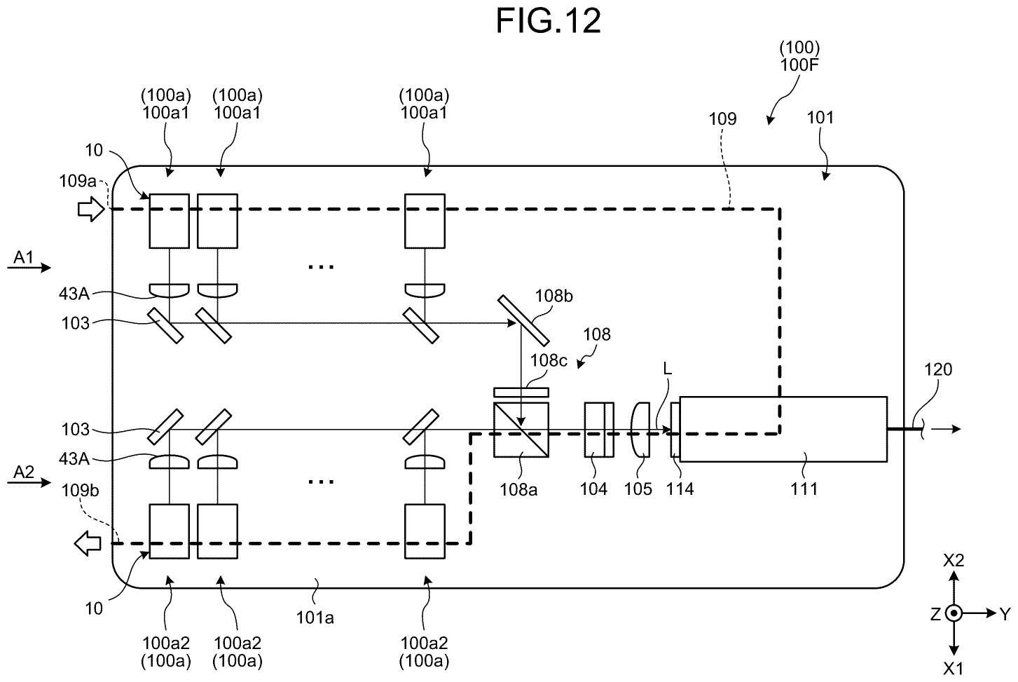

FIG. 12 is a schematic configuration diagram of an optical device 100F (100) of a third embodiment, illustrating a plan view of the interior of the optical device 100F as viewed in the opposite direction to the Z direction.

As illustrated in FIG. 12, the optical device 100F includes the base 101, a plurality of sub-units 100a, a light-combining unit 108, lenses 104 and 105, the transmissive component 114, and the optical fiber 120. The laser beam output from a light-emitting module 10 of each sub-unit 100a is transmitted to the end portion (not illustrated) of the optical fiber 120 via a mirror 103, the light-combining unit 108, and the lenses 104 and 105 of each sub-unit 100a, where it is optically coupled to the optical fiber 120. The optical device 100F may also be referred to as a light emission device.

The base 101 is made of, for example, a material with high thermal conductivity, such as a copper-based material or an aluminum-based material. The base 101 may be composed of a single part or a plurality of parts. Additionally, the base 101 is covered with a cover (not illustrated). The plurality of sub-units 100a, the plurality of mirrors 103, the light-combining unit 108, the lenses 104 and 105, and the end of the optical fibers 120 are all provided on the base 101 and are housed in a housing chamber (not illustrated) formed between the base 101 and the cover. In the present embodiment, the housing chamber is hermetically sealed, but it is not limited to this configuration.

The optical fiber 120 is an output optical fiber and is fixed to the base 101 through the support member 111 that supports the end thereof. The optical power from the optical fiber 120 is, for example, 100 [W] or more.

The sub-unit 100a (100a1 and 100a2) includes the light-emitting module 10, a lens 43A, and the mirror 103. The lens 43A collimates the laser beam from the light-emitting module 10 in the Y direction, that is, in the slow axis.

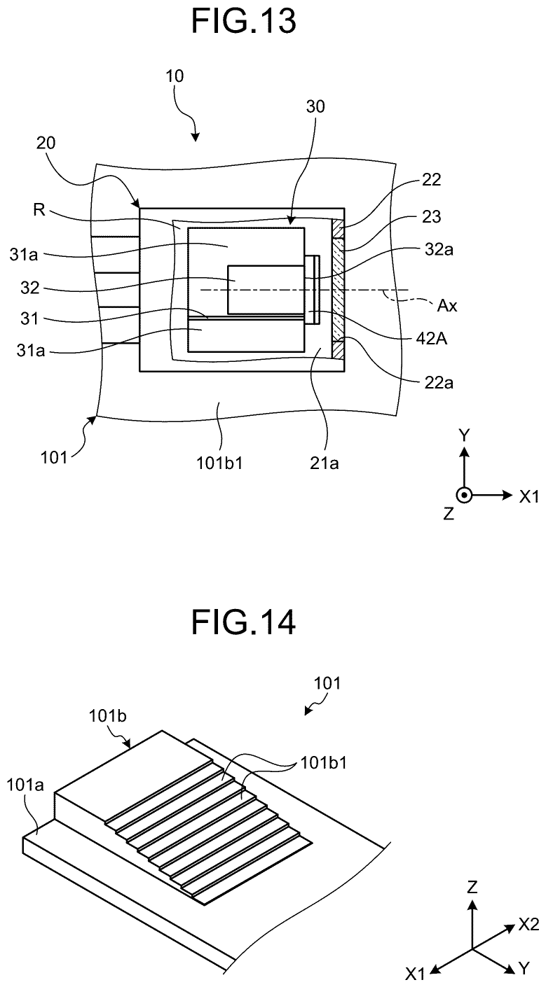

FIG. 13 is a plan view illustrating the light-emitting module 10. As illustrated in FIG. 13, the light-emitting module 10 includes a sub-assembly 30. Moreover, in FIGS. 12 and 13, the optical axis of the laser beam is indicated by a dashed line Ax.

The sub-assembly 30 includes a sub-mount 31, a light emitter 32, and a lens 42A.

The sub-mount 31 has, for example, a rectangular parallelepiped shape that is thin and flat in the Z direction. In addition, the sub-mount 31 is made of an insulating material such as aluminum nitride (AlN), ceramic, or glass. Alternatively, it may be made of a material with relatively high thermal conductivity such as silicon carbide (SiC) or diamond. On the sub-mount 31, a metallized layer 31a is formed as an electrode for supplying power to the light emitter 32.

The light emitter 32 is, for example, a semiconductor laser element, which has a fast axis (FA) and a slow axis (SA) and has the output of 5 [W] or more. The light emitter 32 extends in the X1 direction. The light emitter 32 emits a laser beam in the X direction from an output opening (not illustrated) provided in an exit face 32a located at an end in the X1 direction, which is orthogonal to the Z direction. In the present embodiment, the fast axis of the light emitter 32 runs along the Z direction, while the slow axis runs along the Y direction.

Additionally, the light emitter 32 outputs a laser beam having a wavelength of, for example, 400 [nm] or more and 520 [nm] or less.

The lens 42A is attached to the end facet of the sub-mount 31 in the X1 direction and is arranged adjacent to the exit face 32a of the light emitter 32 in the X1 direction. The lens 42A refracts and transmits the laser beam from the light emitter 32. The laser beam emitted from the light emitter 32 and transmitted through the lens 42A is directed in the X direction. Additionally, the lens 42A is, for example, a collimating lens, which collimates the laser beam on the fast axis. In addition, the lens 42A is an example of an optical component that transmits the laser beam from the light-emitting module 10 to the optical fiber 120. Moreover, the lens 42A may be attached to a casing 20 in the X1 direction with respect to the exit face 32a of the light emitter 32 or may be arranged outside the casing 20.

Further, the light-emitting module 10 has the casing 20 in this example. The casing 20 of the light-emitting module 10 is partially cut away, illustrating the internal configuration of the light-emitting module 10. In the example illustrated in FIG. 13, the sub-mount 31 is mounted on a bottom wall 21 of the casing 20, and the light emitter 32 is provided on the base 101 via the casing 20 and the sub-mount 31. Furthermore, the lens 42A is provided on the base 101 via the casing 20 and the sub-mount 31.

The casing 20 has a box-shaped form and may also be referred to as a housing. The casing 20 forms a housing chamber R within its interior. The casing 20 houses the sub-assembly 30 within the housing chamber R. The casing 20 hermetically seals the housing chamber R, thereby preventing liquid, gas, dust, and the like from affecting the sub-assembly 30 from outside the casing 20.

Additionally, for example, an inert gas or dry air is sealed within the housing chamber R.

The casing 20 is made of, for example, a copper-based material, such as copper or copper alloy.

The bottom wall 21 of the casing 20 is located, for example, at the end of the casing 20 opposite to the Z direction. The bottom wall 21 intersects the Z direction and extends in the X and Y directions. The bottom wall 21 has a rectangular and plate-like shape.

Moreover, the bottom wall 21 of the casing 20 is preferably made of a material with high thermal conductivity, and so it may be made of a different material from the other parts of the casing 20. More specifically, for example, the bottom wall 21 is made of a copper-based material such as copper or copper alloy with high thermal conductivity, while side walls and a lid (not illustrated) of the casing 20 may be made of other materials, such as iron-nickel-cobalt alloy.

A front wall 22, which is one of the side walls of the casing 20, is located at the end of the casing 20 in the X1 direction. The front wall 22 intersects the X1 direction and extends in the Y and Z directions. The front wall 22 is a rectangular and plate-like in shape.

Further, the front wall 22 is provided with an opening 22a. A window member 23 is fitted into the opening 22a. The window member 23 has the property of transmitting laser beams. In other words, the window member 23 is transparent to the laser beam emitted by the light emitter 32.

FIG. 14 is a perspective view of a portion of the base 101. As illustrated in FIG. 14, the base 101 has a protrusion 101b that protrudes from the surface 101a in the Z direction. The protrusion 101b has a plurality of step portions 101b1 where the position of the sub-unit 100a shifts in the direction opposite to the Z direction as it moves toward the Y direction. For each of arrays A1 and A2 in which the plurality of sub-units 100a is aligned in the Y direction at a predetermined interval (e.g., a constant interval), the sub-units 100a are arranged on each of the step portion 101b1. As a result, the position of the sub-unit 100a included in the array A1 in the Z direction shifts in the opposite direction to the Z direction as it moves toward the Y direction, and similarly, the position of the sub-unit 100a included in the array A2 in the Z direction also shifts in the opposite direction of the Z direction as it moves toward the Y direction. With such a configuration, it is possible to input the laser beam, which is parallel and aligned in the Z direction moving in the Y direction, from the respective mirrors 103 to the light-combining unit 108 in each of the arrays A1 and A2. Moreover, the step portion 101b1 may be configured to shift in a direction tilted toward the Y direction or the opposite direction relative to the Z direction, such that the laser beams from the respective mirrors 103 proceed in a direction having a predetermined elevation angle relative to the Y direction.

Then, as illustrated in FIG. 12, the laser beams from the respective mirrors 103 are input to the light-combining unit 108 and are combined in the light-combining unit 108. The light-combining unit 108 includes a combiner 108a, a mirror 108b, and a half wavelength plate 108c.

The mirror 103, the combiner 108a, the mirror 108b, and the half wavelength plate 108c are examples of optical components that transmit the laser beam from the light-emitting module 10 to the optical fiber 120. These optical components are provided directly on the base 101 or indirectly via other members.

The mirror 108b directs the laser beam from the sub-unit 100a of the array A1 to the combiner 108a via the half wavelength plate 108c. The half wavelength plate 108c rotates the polarization plane of light from the array A1.

On the other hand, the laser beam from the sub-unit 100a of the array A2 is directly input to the combiner 108a.

The combiner 108a combines the laser beams from the two arrays A1 and A2. The combiner 108a may also be referred to as a polarization combiner.

The laser beams from the combiner 108a are condensed by the lenses 104 and 105 toward the end of the optical fiber 120 (not illustrated), optically coupled to the optical fiber 120, and transmitted through the optical fiber 120. The lens 104 condenses the laser beams toward the lens 105 on the fast axis. The lens 105 condenses the laser beams toward the end (the end cap, not illustrated) of the optical fiber 120 in the slow axis. The lenses 104 and 105 are examples of optical components that transmit the laser beam from the light-emitting module 10 to the optical fiber 120.

Further, the base 101 is provided with a coolant passage 109 that cools the sub-unit 100a (the light-emitting module 10), the support member 111 (the support member 111A), the lenses 104 and 105, the combiner 108a, and the like. In the coolant passage 109, for example, a coolant, such as a cooling liquid, flows. For example, the coolant passage 109 passes near the mounting side of each component of the base 101, for example, directly below or nearby, and the inner side of the coolant passage 109 and the coolant inside the coolant passage 109 (not illustrated) are thermally connected to the components or parts to be cooled, namely, the sub-units 100a, the support member 111, the lenses 104 and 105, the combiner 108a, and the like. Heat exchange between the coolant and the components or parts is carried out via the base 101, thereby cooling the components. Moreover, although an inlet 109a and an outlet 109b of the coolant passage 109 are provided, for example, at the opposite end of the base 101 in the Y direction, as one example, but they may be provided at other positions. The coolant passage 109 constitutes a cooling mechanism together with a coolant pump, a valve, a control device for the pump and the valve, and the like.

The optical device 100F of the present embodiment includes the transmissive component 114. Thus, in the present embodiment as well, similar effects to those of the above-described embodiments or modifications are obtained by including the transmissive components 114.

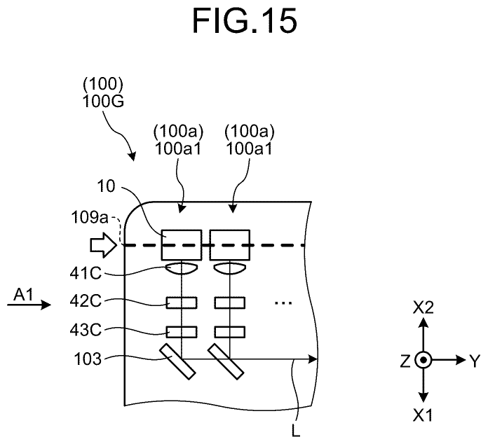

FIG. 15 is a plan view of a part of an optical device 100G (100) of a fourth modification as a modification example of the third embodiment. The optical device 100G of the present modification differs from the third embodiment in the configuration of the sub-unit 100a. Except for this point, the optical device 100G has a similar configuration to the optical device 100F of the third embodiment.

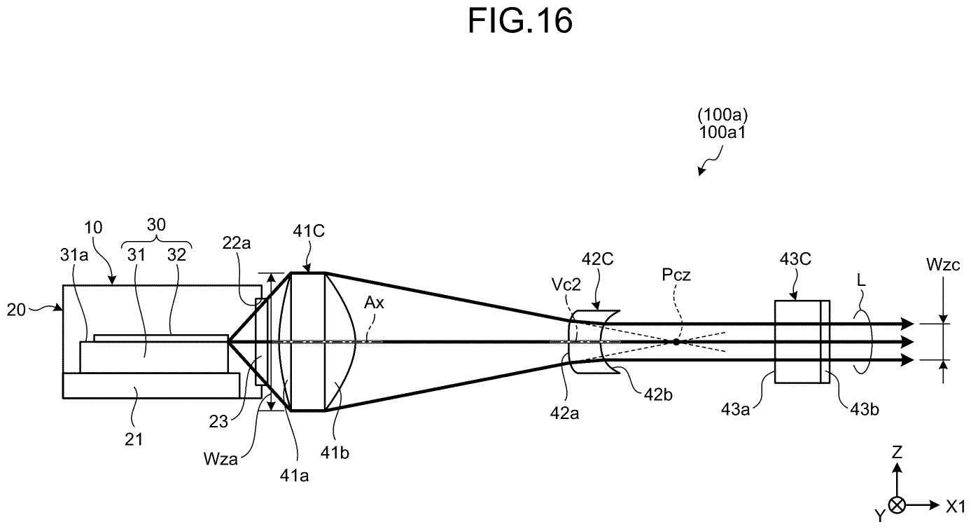

Further, FIG. 16 is a side view illustrating the configuration of the sub-unit 100al (100a). As illustrated in FIG. 16, in the sub-unit 100al, the laser beam L output from the light emitter 32 passes through a lens 41C, a lens 42C, and a lens 43C in this order and is collimated in at least the Z direction and the Y direction. The lens 41C, lens 42C, and lens 43C are all provided outside the casing 20. The lens 41C is an example of an optical component.

In the present modification, the lens 41C, the lens 42C, and the lens 43C are arranged in this order in the X1 direction. The laser beam L output from the light emitter 32 passes through the lens 41C, the lens 42C, and the lens 43C in this order. Additionally, the optical axis of the laser beam L is linear until it exits the light emitter 32 and passes through the lenses 41C, 42C, and 43C, with the fast axis direction of the laser beam L being along the Z direction and the slow axis direction of the laser beam L being along the Y direction.

The lens 41C is positioned slightly apart from the window member 23 in the X1 direction or is in contact with the window member 23 in the X1 direction. The lens 41C may be fixed to the casing 20 with an adhesive or the like.

The laser beam L that has passed through the window member 23 is incident on the lens 41C. The lens 41C is a lens having an axially symmetric shape with respect to a central axis Ax along the optical axis, and is configured as a body of revolution around the central axis Ax. The lens 41C is arranged so that the central axis Ax aligns with the X1 direction and overlaps with the optical axis of the laser beam L. An entrance face 41a and an exit face 41b of the lens 41C each have a rotational surface around the central axis Ax extending in the X1 direction. The exit face 41b is a convex curved surface that protrudes in the X1 direction. The exit face 41b protrudes more significantly than the entrance face 41a. The lens 41C is what is commonly referred to as a convex lens.

The beam width of the laser beam L exiting the lens 41C becomes narrower as it advances in the X1 direction. Moreover, the beam width is defined as the width of a region where the optical intensity is equal to or greater than a predetermined value in the beam profile of the laser beam. The predetermined value is, for example, 1/e² of the peak optical intensity. The lens 41C focuses the laser beam L in the Z direction, the Y direction, and a direction between the Z direction and the Y direction.

The lens 42C has a plane-symmetric shape with respect to a hypothetical central plane Vc2, which is a plane that intersects and is orthogonal to the Z direction. An entrance face 42a and an exit face 42b of the lens 42C each have a cylindrical surface that has a generatrix along the Y direction and extends in the Y direction. The entrance face 42a is a convex curved surface that protrudes in the opposite direction to the X1 direction. Further, the exit face 42b is a concave curved surface that is recessed in the X1 direction.

The lens 42C collimates the laser beam L in the Z direction, that is, along the fast axis, with a beam width Wzc in the Z direction being smaller than a beam width Wza in the Z direction at the entrance face 41a to the lens 41C. The lens 42C is a concave lens in a cross-section orthogonal to the Y direction. The lens 42C may also be referred to as a collimating lens.

Further, the lens 42C is located closer to the lens 41C than a focal point Pcz of the laser beam L in the Z direction caused by the lens 41C. If the lens 42C is located farther from the lens 41C beyond the focal point Pcz in the Z direction, the focal point Pcz in the Z direction will appear on the optical path of the laser beam L between the lenses 41C and 42C. In this case, there is a possibility of undesirable effects, such as the accumulation of dust and debris at the high-energy density focal point Pcz in the Z direction. In this regard, in the present modification, the lens 42C is located closer to the lens 41C than the focal point Pcz in the Z direction, so the laser beam L is collimated by the lens 42C before reaching the focal point Pcz. In other words, according to the present modification, the focal point Pcz in the Z direction does not appear on the optical path of the laser beam L, so it is possible to avoid disadvantages associated with the focal point Pcz.

Moreover, the focal point of the laser beam L in the Y direction (not illustrated) appears between the lenses 41C and 42C, but the energy density at the focal point in the Y direction is not so high, so problems such as accumulation of dust do not occur.

The beam width in the Y direction of the laser beam L, which is output from the light emitter 32 and is passed through the lenses 41C and 42C, widens as it moves in the X1 direction. The lens 43C receives the laser beam L that has expanded in the Y direction and become tapered after passing through the lens 42C.

The lens 43C has a plane-symmetric shape relative to a hypothetical central plane, which is a plane that intersects and is orthogonal to the Y direction. An entrance face 43a and an exit face 43b of the lens 43C have a cylindrical surface that has a generatrix along the Z direction and extends in the Z direction. The entrance face 43a is a plane orthogonal to the X1 direction. Moreover, the exit face 43b is a convex curved surface that protrudes in the X1 direction.

The lens 43C collimates the laser beam L in the Y direction, that is, in the slow axis. The lens 43C is a convex lens in a cross-section orthogonal to the Z direction. The lens 43C may also be referred to as a collimating lens.

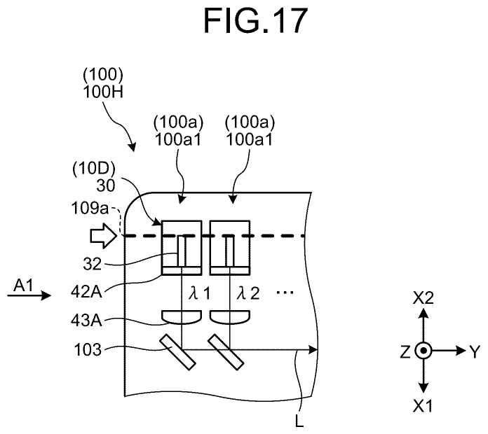

FIG. 17 is a plan view of an optical device 100H (100) of a fifth modification as a modification of the third embodiment. The optical device 100H of the present modification has a configuration similar to the optical device 100F of the third embodiment, except that the plurality of light emitters 32 does not have the half wavelength plate 108c, and the sub-assembly 30 is not housed within the casing 20. Additionally, the plurality of light emitters 32 may output laser beams of mutually different wavelengths (λ1, λ2, . . . , λn−1, λn). In this case, the spacing between the plurality of wavelengths output by the plurality of light emitters 32 may be, for example, 5 [nm] to 20 [nm] between the center wavelengths. Moreover, the light being combined here may include a blue laser beam.

The optical devices 100G and 100H of the fourth modification and the fifth modification as described above have their respective transmissive components 114. Thus, with these modifications as well, effects similar to those of the embodiments and modifications described above may be achieved by incorporating the transmissive component 114.

According to the present disclosure, it is possible to provide an optical device and a method of manufacturing the optical device equipped with a novel and improved configuration.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical device comprising:
a first optical component configured to transmit light between a first end and a second end;
a second optical component configured to either focus and couple the light to the first end or collimate the light emitted from the first end; and
a transmissive component interposed between the first optical component and the second optical component and configured to
transmit the light emitted from the first end or incident on the first end, and
make a distance between the second optical component and the first end longer than in a case without the transmissive component.

2. The optical device according to claim 1, further comprising a mitigating member provided in contact with the first end with a gap from the transmissive component and configured to transmit the light emitted from the first end or incident on the first end to reduce an intensity of light at an interface facing the transmissive component than in a case without the mitigating member.

3. The optical device according to claim 1, wherein the transmissive component is one selected from among a plurality of transmissive components, each having a different thickness in an optical axis direction.

4. The optical device according to claim 1, wherein the transmissive component has a first plane configured as an interface facing the first optical component and a second plane configured as an interface facing the second optical component, the second plane being parallel to the first plane.

5. The optical device according to claim 1, further comprising a first supporting surface partially adjacent to the optical axis direction relative to the second optical component and configured to support the second optical component through a first adhesive.

6. The optical device according to claim 1, further comprising a support member configured to support a supported portion closer to an end in a direction intersecting with the optical axis direction of the transmissive component than a center of gravity of the transmissive component through a second adhesive.

7. The optical device according to claim 6, wherein the support member has a second supporting surface that faces the supported portion in a direction orthogonal to the optical axis direction to support the transmissive component.

8. The optical device according to claim 6, wherein the support member has a third supporting surface that faces the supported portion in the optical axis direction to support the transmissive component through the second adhesive.

9. The optical device according to claim 8, wherein, the transmissive component has an opposing region of a linear shape overlapping with the third supporting surface in the optical axis direction formed, along an end in the direction orthogonal to the optical axis direction, and the opposing region has a width equal to or less than the thickness of the transmissive component.

10. The optical device according to claim 6, wherein the supported portion being supported by the support member is a plurality of the supported portions spaced apart from each other and supported through the second adhesive.

11. The optical device according to claim 10, wherein the supported portion being supported by the support member is three or more of the supported portions spaced apart from each other and supported through the second adhesive.

12. The optical device according to claim 11, wherein the plurality of supported portions spaced apart from each other includes three or more of the supported portions arranged at positions that overlap with vertices of a hypothetical polygon containing the center of gravity of the transmissive component inwardly in a case of being viewed along the optical axis direction.

13. The optical device according to claim 6, wherein the transmissive component has a first region in which both ends in a first direction intersecting with the optical axis direction are supported by the support member, and a second region extending from the first region and the support member in a second direction intersecting with the optical axis direction and the first direction, and the first region has a length in the second direction that is 1.5 times or more than a length of the second region in the second direction.

14. The optical device according to claim 6, wherein the support member is configured to support the first optical component.

15. The optical device according to claim 6, further comprising a mitigating member provided in contact with the first end with a gap from the transmissive component and configured to transmit the light emitted from the first end or incident on the first end to reduce an intensity of light at an interface facing the transmissive component than in a case without the mitigating member,
wherein the support member is configured to support the mitigating member.

16. The optical device according to claim 6, wherein the support member is configured to support the second optical component.

17. The optical device according to claim 6, further comprising:
a component including an optical component; and
a base configured to support the component,
wherein the support member is attached to the base and is made of a material having a value between a thermal expansion coefficient of the base and a thermal expansion coefficient of the transmissive component.

18. The optical device according to claim 1, wherein the first optical component has a numerical aperture of 0.2 or more.

19. The optical device according to claim 1, wherein at least one of an entrance face and an exit face of the transmissive component is covered with an antireflection film.

20. The optical device according to claim 1, further comprising:
an input optical system including at least one first set including
the first optical component,
the second optical component configured to collimate the light from the first end, and
the transmissive component;
an output optical system including at least one second set including
the first optical component,
the second optical component configured to focus and couple the collimated light to the first end, and
the transmissive component; and
a transmission optical system configured to transmit light from the input optical system to the output optical system.

21. The optical device according to claim 20, wherein
the at least one first set includes a plurality of first sets,
the at least one second set includes one second set, and
the transmission optical system is configured to combine the light from the plurality of first sets and couple the combined light to the one second set.

22. A method of manufacturing an optical device including: a first optical component configured to transmit light between a first end and a second end; a second optical component configured to either focus and couple the light to the first end or collimate the light emitted from the first end; a transmissive component interposed between the first optical component and the second optical component and configured to transmit the light emitted from the first end or incident on the first end, and make a distance between the second optical component and the first end longer than in a case without the transmissive component; and a base configured to support the first optical component, the second optical component, and the transmissive component, the method comprising:
a first process of fixing the first optical component to the base;
a second process of provisionally arranging the second optical component, in a state where an adjustment component having a thickness greater in an optical axis direction than the transmissive component and transmitting light is arranged in place of the transmissive component, such that the collimated light inputted into the second optical component transmits through the second optical component and the adjustment component and is focused and coupled at the first end, or such that the light from the first end transmits through the adjustment component and is inputted into the second optical component to be collimated;
a third process of determining the transmissive component having a thickness suitable to a case where the second optical component is fixed in a predetermined position with respect to the base, based on a position in the optical axis direction of the second optical component provisionally arranged in the second process; and
a fourth process of fixing the transmissive component determined in the third process and the second optical component to the base.

23. The method of manufacturing the optical device according to claim 22, wherein, in the fourth process, the second optical component is fixed to a first supporting surface fixed to the base in such a way as to be partially adjacent to each other in the optical axis direction.
